(19) United States
(12) Patent Application Publication
(10) Pub. No.: US 2015/0263280 A1
(43) Pub. Date: Sep. 17, 2015

(54) NONVOLATILE MEMORY

(71) Applicant: Kabushiki Kaisha Toshiba, Minato-ku (JP)

(72) Inventors: Hisao MIYAZAKI, Yokohama (JP); Yuichi YAMAZAKI, Inagi (JP); Tadashi SAKAI, Yokohama (JP)

(73) Assignee: Kabushiki Kaisha Toshiba, Minato-ku (JP)

(21) Appl. No.: 14/644,960

(22) Filed: Mar. 11, 2015

(30) Foreign Application Priority Data
Mar. 13, 2014 (JP) 2014-050159

(51) Int. Cl. H01L 45/00; H01L 27/24

(52) U.S. Cl. CPC H01L 45/1253; H01L 45/08; H01L 45/1233; H01L 45/149; H01L 45/146; H01L 45/14; H01L 27/2463

(57) ABSTRACT

A nonvolatile memory of an embodiment includes first wiring layers of a first conductivity type extending in a first direction, second wiring layers of a second conductivity type extending in a second direction crossing the first direction, memory cells at intersection points of the first and second wiring layers, absorption parts each in contact with peripheral part of each of the memory cells, and an intercalant present in one or both of the memory cell and the absorption part.

### CROSS-REFERENCE TO RELATED APPLICATION

This application is based upon and claims the benefit of priority from Japanese Patent Application No. 2014-050159 Mar. 13, 2014; the entire contents of which are incorporated herein by reference.

### FIELD

Embodiments described herein relate to a nonvolatile memory.

### BACKGROUND

For a cross point memory to work properly, it is necessary to avoid sneak currents through non-selected cells. A method commonly used to avoid sneak currents includes inserting rectifiers in series into a memory device. In this method, however, a thin film and a p-n junction need to be formed for the rectifiers, which can increase the number of process steps and the thickness of cells.

On the other hand, there is concern that the resistance of metal wiring would increase as the metal wiring is made finer in memory devices because the refinement of memory devices is most advanced. It is expected that a new generation of memory devices with a wiring width of around 10 nm themselves can be difficult to operate using metal wiring. Therefore, there has been a demand for a wiring material that can be used in place of metal.

### BRIEF DESCRIPTION OF THE DRAWINGS

FIG. 1 is a schematic cross-sectional view of a nonvolatile memory of an embodiment;

FIG. 2 is a schematic diagram of a nonvolatile memory of an embodiment;

FIG. 3 is a schematic diagram of a nonvolatile memory of an embodiment;

FIG. 4 is a schematic diagram of a nonvolatile memory of an embodiment;

FIG. 5 is a cross-sectional view showing a process for manufacturing a nonvolatile memory of an embodiment;

FIG. 6 is a cross-sectional view showing a process for manufacturing a nonvolatile memory of an embodiment; and

FIG. 7 is a cross-sectional view showing a process for manufacturing a nonvolatile memory of an embodiment.

### DETAILED DESCRIPTION

A nonvolatile memory of an embodiment includes first wiring layers of a first conductivity type extending in a first direction, second wiring layers of a second conductivity type extending in a second direction crossing the first direction, memory cells at intersection points of the first and second wiring layers, absorption parts each in contact with peripheral part of each of the memory cells, and an intercalant present in one or both of the memory cells and the absorption parts.

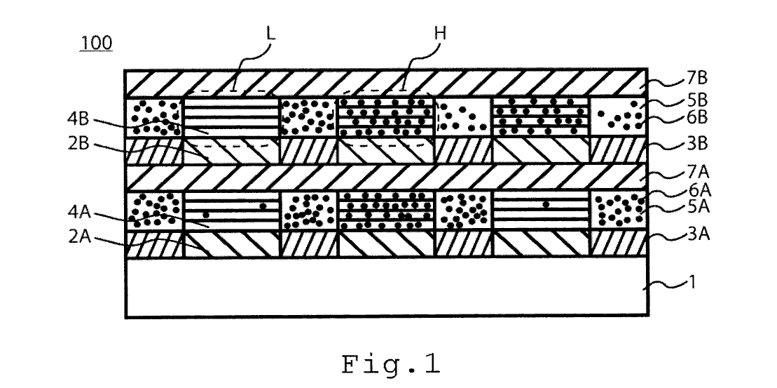

FIG. 1 is a schematic cross-sectional view showing a nonvolatile memory 100 of an embodiment. The nonvolatile memory 100 has a two-layer memory structure and includes a substrate 1, first wiring layers 2A, insulating layers 3A, memory cells 4A, absorption parts 5A, an intercalant 6A, second wiring layers 7A, first wiring layers 2B, insulating layers 3B, memory cells 4B, absorption parts 5B, an intercalant 6B, and second wiring layers 7B. The insulating layers 3B are so arranged that the second wiring layers 7A and 7B are each placed between them, although not shown for the sake of the relationship between the cross-sectional position and direction. In FIG. 1, the nonvolatile memory 100 has first and second wiring layers 2 and 7 alternately stacked each in two layers. The number of stacked layers may be freely changed depending on the design. The conductivity types of the first and second wiring layers 2 and 7 may be reversed.

The substrate 1 may be a Si substrate or the like. An electronic circuit may be formed on the substrate 1.

Hereinafter, a description will be provided, assuming that the first and second conductivity types are p and n types, respectively.

The first p-type wiring layers 2A and 2B are p-type wiring layers extending in a first direction. These wiring layers are arranged parallel to one another. The first wiring layers 2A and 2B include a first p-type layered material. The first layered material contains an element or compound (dopant) between its layers, in its layers, or in its side wall.

The second n-type wiring layers 7A and 7B are n-type wiring layers extending in a second direction. The second direction differs from the first direction. In the schematic view of FIG. 1, the second direction is shifted by 90° from the first direction. The first and second directions, which may be any directions not parallel to each other, are preferably at right angles to each other. These wiring layers are arranged parallel to one another. The second wiring layers 7A and 7B include a second n-type layered material. The second layered material contains an element or compound (dopant) between its layers, in its layers, or in its side wall. Insulating layers 3A or 3B are each provided between these wiring layers. The insulating layers 3A or 3B insulate each wiring layer.

The first wiring layers 2A and 2B and the second wiring layers 7A and 7B are alternately stacked in layers. A p-n or p-i-n junction is provided at each of the intersection points of the first wiring layers 2A or 2B and the second wiring layers 7A or 7B. The p-n or p-i-n junction provides rectification and makes it possible to avoid sneak currents through cells other than the selected cells during reading and writing of the memory cells. Avoiding sneak currents through cells other than the selected cells allows the nonvolatile memory to have a reduced power consumption. Therefore, the nonvolatile memory of an embodiment does not need any diode for preventing sneak currents.

In view of conductivity, the layered material is preferably multilayer graphene having stacked planar graphene sheets. The wiring width is preferably from 1 nm to 20 nm. When graphene is used as the layered material, a wide wiring width can provide a small band gap. For the wiring layer to have a band gap of 0.1 eV or more, the wiring width is preferably 20 nm or less. In addition, for the wiring layer to have a band gap of 0.1 eV or more, the multilayer graphene preferably has an armchair graphene edge. The number of layers in the layered material maybe appropriately selected taking into account the wiring resistance. When multilayer graphene is used as the layered material, the number of layers in it is preferably from 10 to 30. If the number of layers is too small, a relatively large region can change to have high resistance, which may affect the function of the wiring.

The dopant in the layered material of the first wiring layers 2A and 2B preferably includes at least one element of boron, aluminum, gallium, oxygen, sulfur, fluorine, chlorine, bromine, iodine, gold, platinum, iridium, etc. When intercalated with such an element, the first wiring layers 2A and 2B can have p-type conductivity.

The dopant in the layered material of the second wiring layers 7A and 7B preferably includes an element such as nitrogen, phosphorus, arsenic, an alkali metal, an alkaline-earth metal, or a lanthanoid. When intercalated with such an element, the second wiring layers 7A and 7B can have n-type conductivity.

Insulating layers 3A or 3B are each provided between these wiring layers. The insulating layers 3A or 3B insulates these wiring layers from one another. The number of wiring layers may be freely changed depending on the design. The insulating layers 3A and 3B are typically an oxide such as SiO₂. The thickness of the insulating layers 3A and 3B is preferably the same as that of the first wiring layers 2A and 2B and the second wiring layers 7A and 7B.

The memory cells 4A or 4B are each provided at each of the intersection points of the first wiring layers 2A or 2B and the second wiring layers 7A or 7B. The memory cells 4A and 4B each have voids. The memory cells 4A and 4B each preferably include voids or include a layered material such as graphite or a boron compound and voids between its layers. The voids of at least one of the memory cells 4A or 4B preferably contain an intercalant 6A or 6B, which is absorbed and released by the absorption parts 5A or 5B. The resistance of the memory cells 4A or 4B can be changed by changing the concentration of the intercalant 6A or 6B in the memory cells 4A or 4B. The memory cells 4A or 4B store information containing the intercalant 6A or 6B in the memory cells 4A or 4B at a concentration within a required range or at a concentration either higher or lower than a threshold, in other words, the memory cells 4A or 4B having a resistance value within a required range or a resistance value either higher or lower than a threshold resistance. The thickness of the memory cells 4A and 4B is typically, for example, from 0.5 nm to 10 nm.

In a case where the nonvolatile memory stores 1 bit/cell, for example, the memory cell 4 may store the information “0” (for example, the region L in FIG. 1) when it contains the intercalant 6A or 6B at a concentration within a required range A, for example, at a concentration of 0 or not higher than a required concentration X. On the other hand, the memory cell 4 may store the information “1” (for example, the region H in FIG. 1) when it contains the intercalant 6A or 6B at a concentration within a required range B, for example, at a concentration not lower than a required concentration Y (Y>X). The nonvolatile memory of an embodiment may also be, for example, of a multi-bit type with different thresholds for the intercalant concentration.

The absorption part 5A or 5B is an insulator capable of absorbing and releasing the intercalant 6A or 6B. The absorption part 5A or 5B is provided to give and receive the intercalant 6A or 6B to and from the memory cell 4A or 4B. Therefore, at least one peripheral side of the memory cell 4 is in contact with the absorption part 5A or 5B. The peripheral side of the memory cell 4 is, for example, an outer side of the memory cell 4. Preferably, all peripheral sides of the memory cell 4A or 4B are in contact with the absorption parts 5A or 5B. For example, the absorption part 5A or 5B may be made of porous alumina, amorphous carbon, a solid electrolyte, or any other insulating material capable of absorbing and releasing a material different from that of the absorption part 5A or 5B.

At least one of porous alumina, amorphous carbon, and a solid electrolyte may be used to form the absorption part 5A or 5B. Another layer may also be provided between the absorption part 5A or 5B and the memory cell 4A or 4B as long as the intercalant 6A or 6B can be given and received. The thickness of the absorption parts 5A and 5B is preferably the same as that of the memory cells 4A and 4B.

The intercalant 6A or 6B is a substance capable of changing the resistance of the memory cells 4A or 4B. The intercalant 6A or 6B is present in one or both of the memory cell 4A or 4B and the absorption part 5A or 5B. The intercalant 6A or 6B is an element or compound capable of migrating between the memory cell 4 and the absorption part 5 and being stored in the memory cell 4A or 4B and the absorption part 5A or 5B. The intercalant 6A or 6B is preferably, for example, an alkali metal, an alkaline-earth metal, a metal halide, a halogen molecule, an acid, or the like. For example, an alkali metal as the intercalant 6A or 6B can reduce the resistance of the memory cell 4A or 4B. For example, a metal halide, a halogen molecule, or an acid as the intercalant 6A or 6B can increase the resistance of the memory cell 4. The intercalant 6A or 6B migrates between the memory cell 4A or 4B and the absorption part 5A or 5B in response to an electric field applied to the memory cell 4A or 4B.

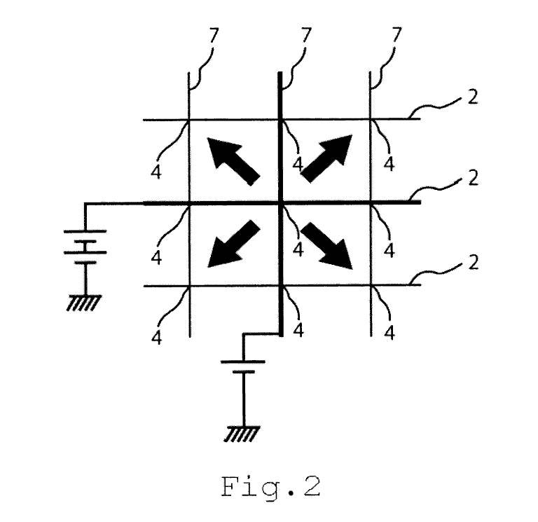

Next, how data is written to, erased from, and stored in the nonvolatile memory of an embodiment will be described with reference to the schematic diagrams of FIGS. 2 to 4. The electric field applying circuit shown in the schematic diagram is a mere example, and any other circuit having the same function may be used for the nonvolatile memory. FIG. 2 is a schematic diagram showing a case where a high concentration of the intercalant 6 is allowed to migrate to the memory cell 4 at any intersection point of the first and second wiring layers 2 and 7. The following description will be provided assuming that the intercalant 6 has a negative charge. In FIG. 2, three first wiring layers 2 intersect three second wiring layers. As shown for the second lines, a voltage is selectively applied to each of the wiring layers. The wiring layers at the positive potential are indicated by a thick line, while the wiring layers at the negative potential are indicated by a thin line. As shown in FIG. 2, when a voltage is applied, an electric field is generated as indicated by the arrows in the drawing, so that the intercalant 6 migrates selectively to the memory cell 4 at the intersection point of the thick lines. In this state, data is written to the memory cell. Thus, the memory cell has the same state as the region H shown in FIG. 1. To accelerate the migration of the intercalant 6, the voltage applied to the first wiring layer may be made different from that applied to the second wiring layer so that a current can be generated to raise the temperature of the memory cell 4.

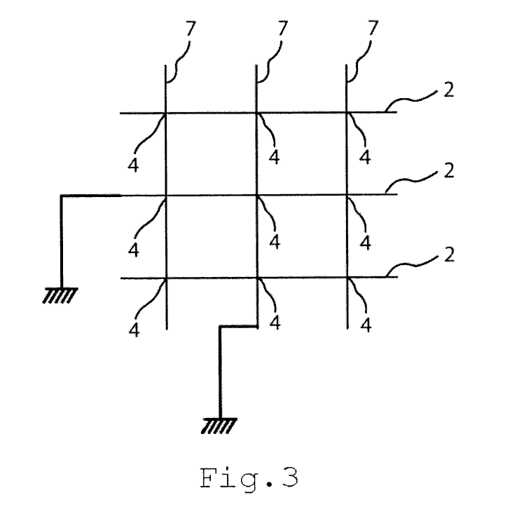

Thereafter, when the application of the voltage is stopped, the electric field disappears as shown in the schematic diagram of FIG. 3. When the electric field disappears, the electric field-induced migration of the intercalant 6 stops.

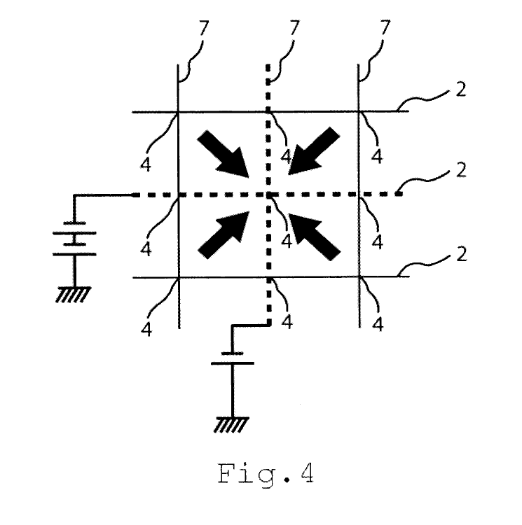

When a potential opposite to that in FIG. 2 is then applied as shown in the schematic diagram of FIG. 4, an electric field opposite to that in FIG. 2 is generated. The wiring layers at the negative potential are indicated by a thick broken line, while the wiring layers at the positive potential are indicated by a thin line. In the state shown in FIG. 4, the intercalant 6 in the memory cell 4 at the intersection point of the thick broken lines selectively migrates to the absorption part 5. In this state, the data is erased from the memory cell. In other words, the memory cell 4 at the intersection point of the thin lines has the same state as the region L shown in FIG. 1. To accelerate the migration of the intercalant 6, the voltage applied to the first wiring layer may be made different from that applied to the second wiring layer so that a current can be generated to raise the temperature of the memory cell 4. Thereafter, when the electric field disappears again as shown in the schematic diagram of FIG. 3, the electric field-induced migration of the intercalant 6 stops.

As shown above, information can be written to, erased from, and stored in any selected memory cell 4. Using other circuits (driver circuits) not shown, data can be read based on the resistance value of a specific memory cell 4 under conditions where the intercalant 6 does not migrate. When the intercalant 6 is of a different type, the intercalant 6 migrates from the memory cell 4 to the absorption part 5 under the conditions shown in FIG. 2, and the intercalant 6 migrates from the absorption part 5 to the memory cell 4 under the conditions shown in FIG. 4. In an embodiment, the electric field applying circuit may be incorporated in the driver circuit of the nonvolatile memory.

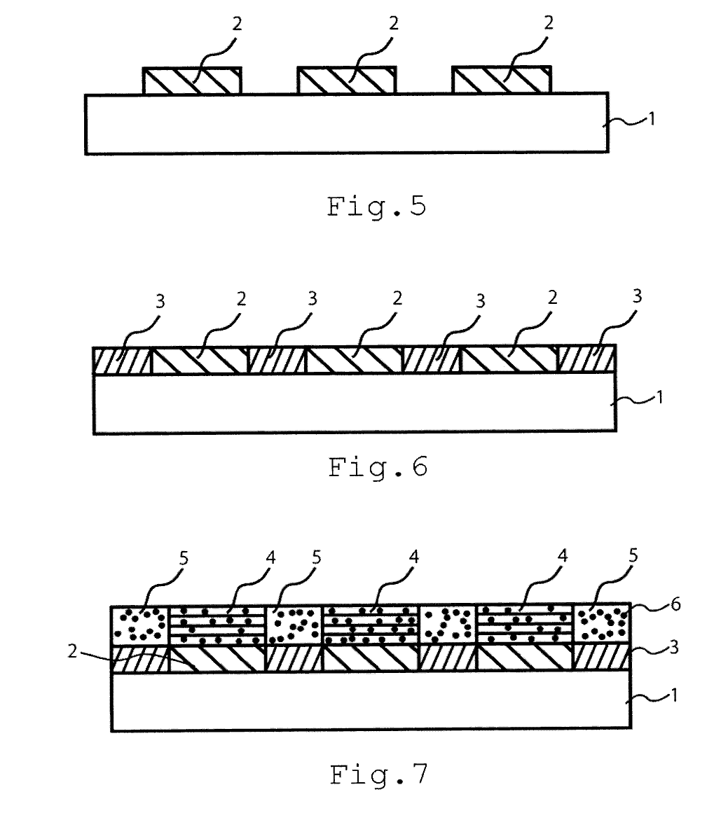

Next, an example of a method for manufacturing a one-layer part of the structure of the nonvolatile memory 100 shown in FIG. 1 will be described with reference to the process sectional views of FIGS. 5 to 7. Firstly, as shown in the process sectional view of FIG. 5, first wiring layers 2 are formed on a substrate 1. A method for this step may include, for example, transferring multilayer graphene by printing onto the substrate 1 and then patterning the multilayer graphene by a fine-processing technique including lithography and etching to forma plurality of wiring parts aligned in a first direction. After the wiring pattern is formed, the doping of the first wiring layers is performed in which the multilayer graphene is doped so as to have p-type conductivity. In the doping of the multilayer graphene, the multilayer graphene may be treated with a dopant atmosphere so that the dopant can be introduced between its layers or into its side wall. Alternatively, the multilayer graphene may be doped before the wiring pattern is formed. The doping of the multilayer graphene may also be performed in such a way that the dopant can be introduced into or between layers during the deposition of the multilayer graphene layer. Alternatively, graphene sheets of multilayer graphene formed in a wiring pattern may be transferred by printing onto the substrate. Alternatively to the transfer by printing, the multilayer graphene may be grown by chemical vapor deposition on a catalyst metal film formed on the substrate. When the multilayer graphene is grown by chemical vapor deposition, the metal film is left between the multilayer graphene and the substrate.

Next, as shown in the process sectional view of FIG. 6, insulating films 3 are formed between the first wiring layers 2. The insulating films are formed over the entire surface of the member of FIG. 5 where the first wiring layers 2 are formed. The insulating films may be formed to cover all the first wiring layers 2. Planarization is then performed by, for example, chemical mechanical polishing until the first wiring layers 2 are exposed, so that the insulating films 3 are obtained.

Next, as shown in the process sectional view of FIG. 7, memory cells 4 and absorption parts 5 are formed. Memory cells 4 are formed as follows when a layered material is included in memory cells 4. A layered material is deposited on the surface of the member of FIG. 5 on which the first wiring layers 2 and the insulating films 3 are formed. The layered material is patterned so that memory cells 4 can be arranged at intersection points of the first wiring layers 2 and second wiring layers 7. An absorption part is then deposited on the entire surface where the memory cells 4 are formed. Planarization is performed by chemical mechanical polishing until the memory cells 4 are exposed. An intercalant 6 is then introduced into the memory cells 4 and the absorption parts 5. The member of FIG. 7 maybe treated with an atmosphere containing the intercalant 6. In the treatment, for example, the member of FIG. 7 maybe exposed to a gas or chemical solution containing the intercalant. In this step, heating at a temperature of about 100° C. to about 700° C. may be performed to facilitate the absorption of the intercalant.

Second wiring layers 7 are then formed. The second wiring layers 7 are formed in such a way that the memory cells 4 are sandwiched between the first and second wiring layers 2 and 7. The second wiring layers 7 may be formed using the same process, including the patterning, as for the first wiring layers 2, except that a second intercalation compound is used to form n-type wiring layers. However, when the memory cells 4 are voids, the second wiring layers 7 should be formed by transfer printing. Insulating layers 3 are then each formed between the second wiring layers 7 in the same way as in the formation of the first wiring layers. Thereafter, the above process may be repeated so that nonvolatile memories can be three-dimensionally integrated.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile memory comprising:
first wiring layers of a first conductivity type extending in a first direction;
second wiring layers of a second conductivity type extending in a second direction crossing the first direction;
memory cells at intersection points of the first and second wiring layers;
absorption parts each in contact with peripheral part of each of the memory cells; and
an intercalant present in one or both of the memory cells and the absorption parts.

2. The memory according to claim 1, wherein the memory cells include a void.

3. The memory according to claim 1, wherein the memory cells include a void and a layered material.

4. The memory according to claim 1, wherein the first and second wiring layers are multilayer graphene layers.

5. The memory according to claim 1, wherein the intercalant is a substance capable of changing the resistance of the memory cells and capable of migrating between any selected one of the memory cells and the absorption part in contact with a peripheral part of the selected one of the memory cells in response to an electric field generated in the selected one of the memory cells.

6. The memory according to claim 1, wherein the absorption parts have insulating properties.

7. The memory according to claim 1, wherein the absorption parts comprise at least one of porous alumina, amorphous carbon, and a solid electrolyte.

8. The memory according to claim 1, further comprising a circuit configured to apply an electric field to any selected one of the memory cells.

9. The memory according to claim 4, wherein the multilayer graphene layers have a band gap of at least 0.1 eV.
